(19) United States
(12) Patent Application Publication
(10) Pub. No.: US 2011/0048495 A1
(43) Pub. Date: Mar. 3, 2011

(54) Photovoltaic module containing a metal/polymer stack for enhanced cooling and reflection

(76) Inventor: Satyanarayana Rao Peddada, San Jose, CA (US)

(21) Appl. No.: 12/661,003

(22) Filed: Mar. 10, 2010

Related U.S. Application Data
(63) Continuation-in-part of application No. 12/583,888, filed on Aug. 26, 2009.

(51) Int. Cl. H01L 31/052

(52) U.S. Cl. 136/246

(57) ABSTRACT

A method and apparatus for efficiently cooling a PV module for converting solar radiation to electrical energy comprises a means for defining a thermally conductive path characterized by a steep thermal gradient (delta T) provided interiorly, adjacent the back surface of the solar cells and having opposite ends extending exteriorly around at least a portion of a back facing exterior surface of the PV module. Heat developed from the solar cells is efficiently conducted away from the solar cells along the steep thermal gradient to the exterior shaded surface of the PV module where heat is quickly dissipated to the ambient surroundings. The invention applies to both polycrystalline and single crystalline, as well as to thin film PV modules.

### CROSS REFERENCE TO RELATED APPLICATION

This application claims the benefit of U.S. patent application Ser. No. 12/583, 888, filed Aug. 26, 2009.

### BACKGROUND

1. Field of the Invention

The field of the invention relates generally to photovoltaic (PV) modules. In particular, the field of the invention pertains to thin film PV modules and to PV modules constructed from conventional x-Si or p-Si cells, wherein a metal/polymer stack characterized by a high back reflectance and high thermal conductivity is provided for defining a low resistance thermal path for conducting heat from inside the PV module to the external ambient surroundings for increased cooling and improved photovoltaic efficiency.

2. Background of Related Art

This invention applies to thin film PV modules and to PV modules constructed from conventional x-Si (single crystal silicon) or p-Si (polysilicon) cells. Such x-Si and p-Si modules do not have back glass, but instead use a polyvinyl fluoride (PVF) back sheet that provides a moisture bather.

A conventional thin film PV module typically consists of a thin film metal reflecting layer or a printed layer of white ink or paint applied over and behind the thin film stack to reflect unabsorbed light back into the thin film stack. The lamination material is usually polyvinyl butyral (PVB), or a plastic layer (PVF) such as DuPont TEDLAR® used between the front and back glass pieces in the laminating process. Such a plastic sheet typically is used in x-Si and p-Si PV modules. Alternatively, ethylene vinyl acetate, also known as EVA, may be used. Such conventional lamination materials are optically clear, and provide no reflectance.

In such a conventional thin film PV module, providing reflectance to the back of the thin film stack is complex and expensive, since it requires extra process steps, adds process time, and would require significant capital expenditure for processing equipment.

A further disadvantage in the construction of a conventional thin film PV module is that the lamination materials are not filled and are not thermally conductive. Conventional thin film lamination materials tend to be thermally insulative and disadvantageously cause retention of heat upon prolonged exposure to the sun.

Accordingly, in high intensity sunlight, photovoltaic solar cells become very hot due to the absorption of sunlight and its conversion to heat. Both PV cells and their associated modules exhibit reduced efficiency as their temperature increases. The PV cells which absorb the light and become hot are sandwiched inside the module and are thermally insulated from the outside ambient temperature.

Consequently, what is needed is a process for construction and assembly of thin film PV modules that would enhance the capability of the thin film stack to dissipate heat and thereby increase photovoltaic conversion efficiency in high temperature conditions. It also would be desirable that such construction be provided by a cost effective and straightforward process.

Thus, what is also needed is a system and method for constructing a PV module that maximizes kilowatt-hour production while minimizing investment in component cost and installation.

### SUMMARY

In accordance with the foregoing and other objectives, an aspect of the invention improves the efficiency of silicon PV cell modules and thin film PV modules by providing a means for defining a thermally conductive path characterized by a steep thermal gradient (delta T) interiorly, adjacent the back surface of the solar cells and having opposite ends extending exteriorly around at least a portion of a back facing exterior surface of the PV module. Heat developed from the solar cells is efficiently conducted away from the solar cells along the steep thermal gradient to the exterior shaded surface of the PV module where heat is quickly dissipated to the ambient surroundings. The means for providing a thermally conductive path may comprise a metal sheet or foil characterized by high reflectance with respect to the solar spectrum.

In another aspect of the invention, the means for defining a thermally conductive path comprises a thermally conductive, reflective material provided adjacent or integrated with a lamination material including any suitable polymer, such as PVB, used as a back sheet that is provided adjacent the back side of the active light absorbing layer to seal the front sheet to the back sheet of a thin film PV module.

An aspect of the invention applies to either a PV module made with a thin film photovoltaic layer, or to PV modules made with x-Si or p-Si cells. In such applications, the means for defining a thermal path comprises a thermally conductive material provided adjacent to or close to the active light-absorbing surface, that defines a thermal path to the exterior of the module for dissipating heat built up around the solar cells directly to the ambient surroundings. By including the high thermally conductive material in the lamination layer of a thin film PV module, better thermal separation is achieved between the active surface and the backing layer resulting in rapid conduction of heat to the outside surface of the PV module.

In another aspect of the invention, with respect to thin film PV modules that feature a light absorbing thin film stack, the thermally conductive lamination material comprises a thermal transport layer or sheet adjacent the thin film stack in the interior of the PV module. Opposite ends of the thermal transport sheet are wrapped around at least a portion of the exterior of the rearward facing surface of the PV module, thereby defining a steep thermal gradient for conduction of heat from the heated interior of the PV module to the cooler exterior, where heat is dissipated into the ambient surroundings.

Opposite ends of the thermally conductive sheet are wrapped around at least a portion of the back surface of the PV module and that function as heat dissipating members. The opposite ends located outside the PV module are configured such that the surface area of the heat dissipating members is greatly increased to increase the thermal gradient (delta T) to facilitate heat transfer from the interior of the PV module along a thermally conductive path to the ambient surroundings where heat is dissipated. The heat dissipating members may be provided with corrugations or with a plurality of other heat exchange or heat transfer surfaces such as slanted shelves, fins, serpentine paths, or the like that increase surface area in the air cooled outer surface of the PV module and thereby accelerate heat transfer from the heated interior of the PV module to the exterior.

The thermally conductive sheet thus defines a path for actively conducting heat from the heated interior of the PV module to the shaded, rearward facing exterior of the PV module and enables the light absorbing portion of the thin film PV module to be cooler in high sunlight conditions.

An aspect of the invention also increases the photocurrent of the active layer of a thin film stack by using a highly reflective material, such as aluminum, as the thermally conductive lamination material used to adhere the back sheet to the front sheet of a PV module. In a thin film application, the front sheet glass of the module contains the photovoltaic thin film stack. Light passing through the thin film stack on the front sheet of the glass generates a photocurrent. Some of the incident light is not absorbed in the thin film stack and passes through the active layer into the lamination material. The lamination material is characterized by highly reflective material such as aluminum having a reflectance value on the order of 95 percent or more for a broad range of solar radiation. Thus, unabsorbed light passing through the thin film stack is reflected back into the active layer, thereby generating additional photocurrent. This aspect of the invention advantageously eliminates the need for a separate paint layer or other reflective material to be applied to the thin film stack.

### BRIEF DESCRIPTION OF THE DRAWINGS

The drawings are heuristic for clarity. The foregoing and other features, aspects and advantages of the invention will become better understood with regard to the following description, appended claims and accompanying drawings in which:

FIG. 1 is a side sectional view of a conventional PV module.

FIG. 2 is a side sectional view of a PV module with a highly reflective and thermally conductive foil in accordance with an aspect of the invention.

FIG. 3A is a side sectional view of a thin film PV module with a highly reflective and thermally conductive foil in accordance with an aspect of the invention.

FIG. 3B is a side sectional view of an alternate embodiment of the thin film PV module of FIG. 3A.

### DESCRIPTION OF THE PREFERRED EMBODIMENTS

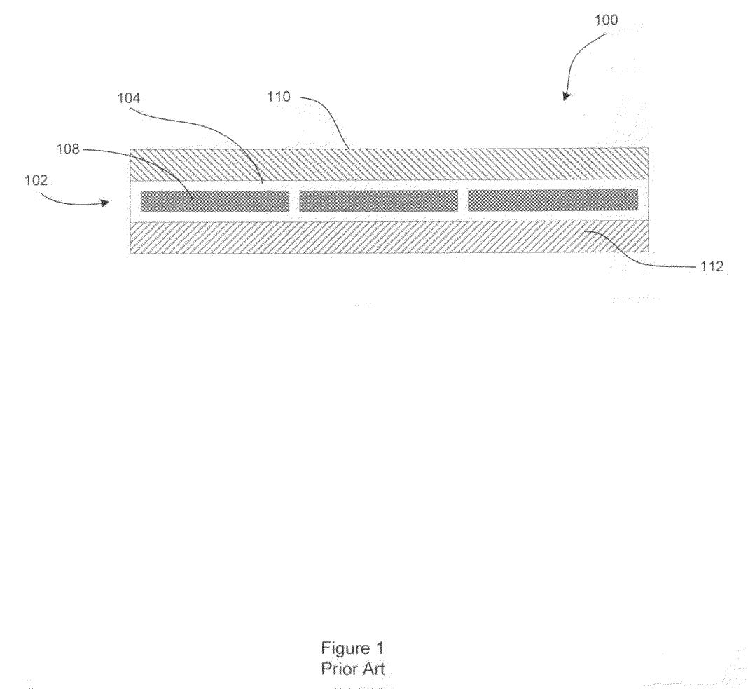

Referring to the drawings, FIG. 1 shows a cross section of a conventional single crystal silicon (x-Si) or polysilicon (p-Si) module 100. Silicon module 100 comprises a plurality of PV cells 102 enclosed in a laminated plastic 104. Such x-Si and p-Si modules do not have back glass, but instead use a PVF back sheet that provides a moisture barrier.

The lamination plastic adjacent the light incident planes 108 of PV cells 102 is transparent. A front cover glass 110 is provided adjacent the transparent lamination plastic for protection against the elements. The backside of the lamination plastic is typically sealed with a PVF film 112 such as Dupont TEDLAR® or other fluoro polymer. Moisture penetration and condensation on the PV cells is responsible for the majority of long term PV module failures. The most vulnerable sites for moisture penetration are at the interface between the cells and encapsulating lamination material 104, and at the interfaces between the glass 110, lamination material 104, and PVF film 112, respectively.

Accordingly, the lamination materials are selected to be highly resistant to penetration or ingress of gases, vapours and liquids. As a result, the materials encapsulating the solar cells develop considerable heat build up within the PV module. In the case of the x-Si and p-Si modules, the thermal path is through the lamination material and front glass, and rear lamination material and the backing sheet, which is usually PVF. Thus, there is only a limited way for the heat to escape. Such heat build up in conventional x-Si and p-Si PV modules reduces efficiency as photovoltaic degradation rates approximately double for each 10° C. increase in temperature.

Conventional thin film PV modules likewise suffer degradation in output efficiency due to heat build up, and rely on thermal conduction through the plastic lamination material and the front and back glass in order to cool the higher temperature light absorbing layers. The lamination materials and the front and back glass are not highly thermally conductive, so the cooling of the light absorbing layers is rather poor and inefficient.

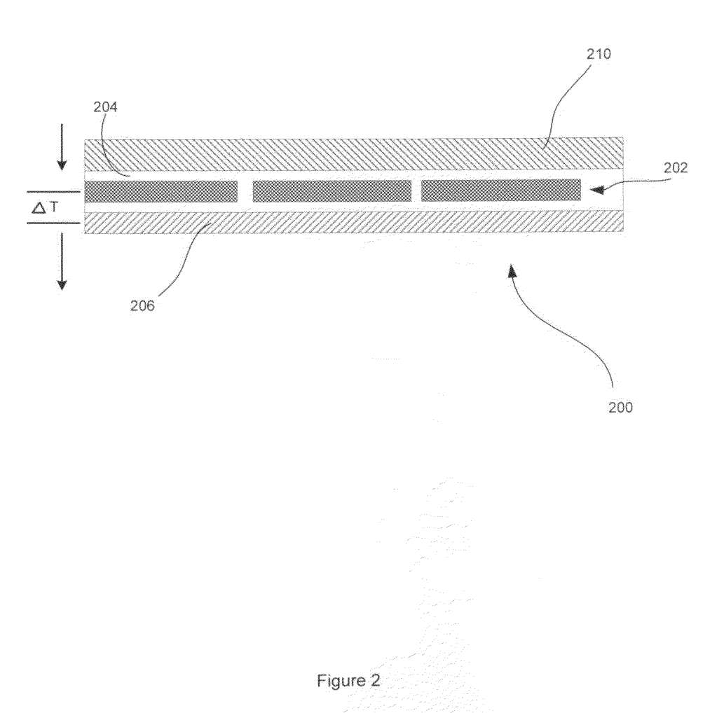

In order to overcome the foregoing disadvantages and deficiencies in conventional PV modules, an aspect of the invention as shown in FIG. 2 provides an improved x-Si or p-Si module 200, comprising a plurality of PV cells 202. The PV cells typically are enclosed in a lamination plastic 204. A transparent protective cover such as a front glass 210 is provided over the light incident side of the plastic 204. A metal foil or sheet 206 is provided over the back side of the PV module 200. A first surface of metal foil sheet 206 is provided adjacent the plastic sheet 204 and is in close proximity to the solar cells 202. The opposite surface of the foil sheet 206 forms the back or shaded exterior surface of the PV module 200. The metal foil 206 comprises a highly reflective material characterized also by high thermal conductivity and emissivity. Preferably, the metal foil sheet 206 is aluminum or composite thereof, having a thermal conductivity value on the order of 230 W/mK at 25° C. or greater.

In addition, the first surface of foil sheet 206 adjacent the solar cells 202 is treated by well known techniques to have a reflectance value in a range of 90 percent or more and preferably 95 percent or more with respect to solar radiation wavelengths in a range of about 450 to 900 nm. The exterior side of metal foil 206 forms the back or shaded side of the PV module and is open to the ambient surroundings. A thermal gradient, Delta T, is established between the heated solar cells 202 and the shaded exterior back side 206 of the PV module 200. Thus, due to the high delta T and thermal conductivity of the foil sheet, heat developed from the solar cells 202 quickly dissipates through to the back side of the foil sheet 206 into the surrounding air, producing a significant cooling effect on the solar cells. The high emissivity of the metal foil 206 effectively forms a thermal path for conducting heat away from the interior of the PV module that cools the PV module, resulting in higher photovoltaic efficiency.

In another aspect of the invention, the high reflectance value of the foil sheet with respect to solar radiation reflects unabsorbed sunlight from the space around the PV solar cells back into the lamination material and the front glass where it becomes light guided until it can be directed onto the light incident surface of solar cells 202. Thus, the high diffuse reflectance of metal foil sheet 206 also increases photocurrent generation by the solar cells. The silicon PV cells are much thicker than thin films, so any light incident on the front surface of the silicon PV cell is totally absorbed. However, the light that falls on the area between the cells can be diffusely reflected and will eventually find its way to the front surface of the PV cell, generating additional power.

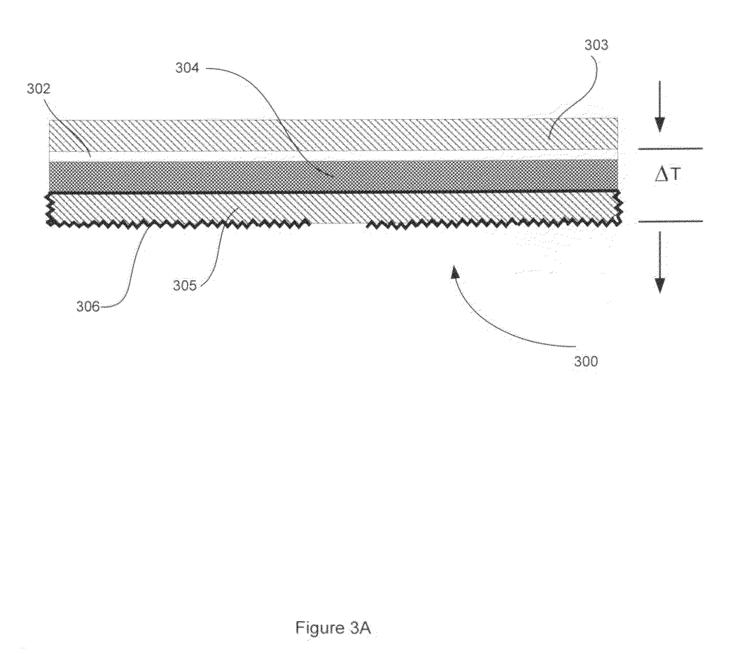

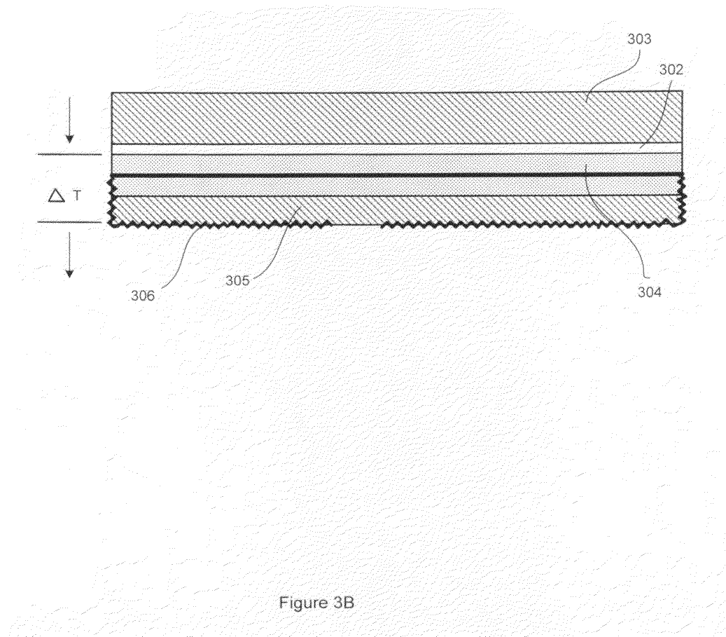

In accordance with another aspect of the invention, FIG. 3A shows an improved thin film PV module 300 incorporating a means for defining a thermally conductive path or thermal transport path through foil 306 characterized by a thermal gradient (delta T). for transporting heat from the active thin film stack to the cooler exterior surface 305 of the PV module The thermally conductive path is provided interiorly, adjacent the back surface of the active thin film stack/solar cells 302 and has opposite, distal ends extending exteriorly around at least a portion of back facing surface 305 of the PV module. Preferably, The means for defining a thermal transport path comprises a metal sheet or metal foil 306 characterized by high thermal conductivity and emissivity that defines a thermal path for effectively dissipating heat built up in the thin film stack 302 to the ambient surroundings. The metal foil functions as a thermal transport layer for improved cooling and photovoltaic efficiency as well as a reflective layer for reflecting unabsorbed light back into the thin film stack so that more photocurrent is generated.

Referring to FIG. 3A, an improved thin film PV module 300 comprises light absorbing thin film stack 302 having a first or light incident surface protected by a transparent protective cover such as front glass 303 and having a second surface opposite the light incident surface. The thin film stack is provided in accordance with known techniques on an appropriate substrate for lamination to a plastic backing or sheet 304. Plastic backing 304 preferably comprises any suitable transparent polymer material such as PVB or a plastic material.

Metal foil 306 is provided adjacent to the lamination backing 304 of the light-absorbing stack 302. Thus, the interior portion of the metal foil 306 is located in close proximity to the active PV thin film stack where heat is developed from incident solar radiation. Foil 306 further has opposite ends that extend to the exterior of the thin film PV module where the ends are wrapped around at least a portion of the exterior of a back glass sheet 305. Metal foil 306 is adhered to the back glass sheet 305 by means of an adhesive. The metal foil 306 comprises a material, such as aluminum or composite thereof, that is characterized by high thermal conduction and thermal emissivity as well as high reflectivity.

Portions of foil 306 provided on the exterior of the thin film PV module 300 are configured to increase the surface area of the foil in contact with the outside ambient surroundings. The heat dissipating members may be provided with corrugations or with a plurality of other heat transfer surfaces such as slanted folds, partitions, serpentine paths or the like that increase surface area of the foil in the air cooled outer surface of the PV module and the thereby accelerate heat transfer from the heated interior of the PV module to the exterior. Thus, exterior portions or ends of foil 306 function as heat dissipating members and define a conductive thermal path to facilitate heat transfer from the heated interior adjacent the active layer, the light-absorbing stack 302, to the ambient surroundings.

Although the present invention has been illustrated as having corrugations, or straight, vertically oriented partitions and vertically oriented heat dispensing surfaces, it is contemplated that equivalent shaped partitions that increase the surface area of the exterior portions of foil can be utilized. For example, exterior portions of foil 306 can be folded or arranged in a serpentine manner. The orientation or geometry of the spaced corrugations is not critical to the present invention. It is important is that the heat conducting interior portion of the foil must be located substantially adjacent or close to the active layer, light absorbing stack 302, and that the foil or metal provide a thermally conductive path to the exterior of the module for accelerated transfer of heat to the ambient surroundings.

Preferably the thermal conductivity value for the foil 306 is on the order of 230 W/mK at 25° C. The preferred range of thickness for the foil is on the order of approximately 0.38 mm. The metal foil is commercially available from several companies, including All Foils, Inc., 16100 Imperial Parkway, Cleveland, Ohio 44149 U.S.A.

It will be appreciated that metal foil 306 acts as a thermal transport layer for conducting heat developed by the light absorbing thin film stack away to the cooler exterior, shaded side of the PV module where heat is dissipated. Metal foil 306 defines a thermal path beginning at the interior of the module 300, and extending around the outside of the back glass 305 for effectively conducting heat away from the center of the thin film PV module to the external ambient surroundings on the shaded side of the PV module 300 where heat is dissipated. The cooler exterior surface of the foil 306 on the shaded side of the PV module sets up a temperature gradient for enabling heat to be effectively dissipated at the exterior and back sides of the PV module 300. This feature allows the PV module to be cooler in conditions of prolonged exposure to direct sunlight. This aspect of the invention also effectively increases the cooling rate of the PV module by locating a heat sinking material in close proximity to the active PV thin film stack, and providing a thermal path to the ambient air on the outside, for effectively cooling the PV module.

In another aspect of the invention, metal foil 306 also is highly diffusely reflective with respect to the solar spectrum. The foil 306 is characterized by a reflectance value in a range of 90 percent or more and most preferably by a reflectance value of 95 percent or more with respect to solar radiation having wavelengths in a range of about 450 to 900 nm. Foil 306 is thus capable of reflecting unabsorbed light back through the active layers of thin film stack 302. In this aspect of the invention, the metal foil also may be contained in or integrated with a substantially transparent lamination material 304. Lamination material 304 used to adhere the back sheet 305 to the front sheet 303 of the PV module. The back sheet can also be sandwiched between two sheets of lamination material so that the lamination material provides the adhesion to the glass sheets, as in the case of the prior art conventional thin film PV modules. As is well known, the front sheet glass 303 of the module contains the photovoltaic thin film stack.

Light passing through the thin film stack on the front sheet of glass generates a photo current. However, not all of the incident light is absorbed in the thin film stack. Advantageously, the highly reflective quality of the foil material 306 reflects unabsorbed light back into the thin film stack 302 such that additional photocurrent is generated, resulting in improved module efficiency.

Referring to FIG. 3B, an alternate embodiment of a thin film PV module 300 is provided, wherein a metal foil 306 is positioned between two layers or sheets of lamination plastic 304. In this non-limiting example, the front glass has a thickness of approximately 3.2 mm on which is provided a light absorbing thin film stack 302. A layer of lamination plastic 304 approximately 0.38 mm thick is provided adjacent the light absorbing thin film stack 302. A metal foil 306 is positioned between the first lamination layer and a second layer of lamination plastic 304, also having a thickness on the order of approximately 0.38 mm. The second layer of lamination plastic is adhered to the back glass 305 by well known techniques. The metal foil 306 extends around and is adhered to a portion of the exterior surface of the back glass 305.

It will be appreciated that the metal foil 306 for providing a thermally conductive path may be pre-laminated within a single sheet of lamination plastic 304 and provided on a light absorbing stack 302 for adhering a back glass 305 to the module in a single process step.

The metal foil 306 is characterized by high reflectivity as well as high emissivity. The metal foil 306 is provided in close proximity (0.38 mm) to the light absorbing thin film stack 302, and thereby transports heat away from the inside of module 300 to the outside ambient surroundings. As explained with reference to FIG. 3A. The high reflectivity of the foil material 306 with respect to solar radiation also reflects unabsorbed light back into the thin film stack 302 for additional photocurrent generation and efficiency.

While the invention has been described in connection with what are presently considered to be the most practical and preferred embodiments, it is to be understood that the invention is not limited to the disclosed embodiments, but rather is intended to cover various modifications and equivalent arrangements within the scope of the following claims.

I claim:

1. A PV module for converting solar radiation to electrical energy comprising:
a plurality of solar cells forming a light absorbing surface provided adjacent a light incident cover for converting the solar radiation to electrical energy;
a back facing exterior surface opposite the light incident cover;
a thermally conductive path characterized by a steep thermal gradient (delta T) provided between the solar cells and back facing exterior surface for conducting heat away from the solar cells to the ambient surroundings.

2. A PV module according to claim 1, wherein the thermally conductive path comprises an aluminum, or composite thereof, metal sheet characterized by a thermal conductivity value on the order of 230 W/mK at 25 deg. C. or greater.

3. A PV module according to claim 2, wherein the metal sheet has opposite ends extending externally around at least a portion of the back facing exterior surface of the PV module.

4. A PV module according to claim 3, wherein at least a portion of the externally extending opposite ends of the thermally conductive sheet are provided with a series of corrugations or other means for increasing surface area and dissipating heat.

5. A PV module according to claim 4, wherein at least a portion of the externally extending opposite ends of the thermally conductive sheet are elongated in a serpentine path for increased surface area for dissipating to the external ambient surroundings.

6. A PV module according to claim 1, wherein the solar cells are single crystal silicon, or polycrystalline silicon.

7. A thin film PV module incorporating a thermal transport layer for improved cooling and photovoltaic efficiency comprising:
a light absorbing thin film stack having a light absorbing surface provided on a transparent substrate;
a back sheet provided adjacent the thin film stack opposite the light absorbing surface, having an exterior surface for sealing the light absorbing thin film stack from the elements;
a thermal transport layer provided between the film stack and the back sheet, the thermal transport layer having opposite ends configured for establishing a low resistance thermal path characterized by a steep thermal gradient between the thin film stack and exterior of the back sheet for conducting heat developed from the light absorbing thin film stack to the external ambient.

8. A thin film PV module as in claim 7, wherein the thermal transport layer comprises a metal having opposite heat dissipating ends provided over at least a portion of the exterior back sheet for dissipating heat conducted along the thermal path away from the thin film stack.

9. A thin film PV module as in claim 8, wherein the metal is characterized by thermal conductivity on the order of 230 W/mK at 25° C. or greater.

10. A thin film PV module incorporating a thermal transport layer for improved cooling and photovoltaic efficiency comprising:
a light absorbing thin film stack having a light absorbing surface provided on a transparent substrate and having an interior surface opposite the light absorbing surface;
a back sheet provided adjacent the interior surface of the thin film stack for sealing the thin film stack against the elements, and forming an exterior back surface of the PV module;
a thermal transport layer provided interiorly in the back sheet and having opposite ends extending around at least a portion of the exterior back surface for defining a thermal path for conducting heat developed by the light absorbing thin film stack to the ambient surroundings.

11. A thin film PV module as in claim 10, wherein the thermal transport layer comprises a metal sheet defining a thermal path for conducting heat away from the light absorbing stack to the exterior of the PV module where heat is dissipated.

12. A thin film PV module as in claim 11, wherein the metal foil is characterized by thermal conductivity on the order of 230 W/mK at 25° C. or greater.

13. A method for cooling a PV module, having a light incident surface and a shaded back surface, a plurality of solar cells defining a light absorbing surface disposed adjacent the light incident surface, and forming an interior surface opposite the light incident surface, comprising the steps of:
adhering a thermally conductive material to the interior surface;
extending opposite ends of the thermally conductive material externally around the shaded back surface, such that the thermally conductive material provides a thermal path for dissipating heat built up by the solar cells to the ambient surroundings.

14. A method for cooling a thin film PV module having a light incident front sheet, a shaded back surface, a thin film stack including a light absorbing surface provided on the light incident front sheet, and having an interior surface opposite the light absorbing surface, comprising the steps of:
providing a thermally conductive material to the interior surface of the thin film stack for defining a thermal pathway for conducting heat away from the thin film stack;
extending opposite ends of the thermally conductive material externally around the shaded back surface of the PV module;
configuring the opposite extended ends to provide greater surface area for dissipating heat conducted from the thin film stack to the ambient surroundings.

15. A method for providing enhanced cooling and photocurrent generation in a thin film PV module having a light incident front sheet, a shaded back sheet, a thin film stack comprising a light absorbing surface adjacent the light incident front sheet, and an interior surface opposite the light absorbing surface, comprising the steps of:
providing a substantially transparent lamination backing adjacent the interior surface of the thin film stack for laminating the thin film stack to the back sheet;
providing a thermally conductive material such as a metal sheet, between the lamination backing and the back sheet, the material being characterized by thermal conductivity on the order of 230 W/mK at 25° C. or greater;
corrugating or folding opposite ends of the thermally conductive material to increase surface area for heat dissipation; and
wrapping at least a portion of the corrugated ends around the exterior of the back sheet for conducting heat developed by the light absorbing thin film stack to the ambient surroundings.
